(19) United States
(12) Patent Application Publication
(10) Pub. No.: US 2016/0359058 A1
(43) Pub. Date: Dec. 8, 2016

(54) Selective Plating of Copper on Transparent Conductive Oxide, Solar Cell Structure and Manufacturing Method

(71) Applicants: Stanislau Herasimenka, Tempe, AZ (US); Mikhael Reginevich, Brest (BY)

(72) Inventors: Stanislau Herasimenka, Tempe, AZ (US); Mikhael Reginevich, Brest (BY)

(21) Appl. No.: 15/176,971

(22) Filed: Jun. 8, 2016

Related U.S. Application Data
(60) Provisional application No. 62/172,428, filed on Jun. 8, 2015.

(51) Int. Cl. H01L 31/0224; H01L 31/0747

(52) U.S. Cl. CPC H01L 31/022425; H01L 31/022466; H01L 31/0747

(57) ABSTRACT

A solar cell includes a silicon substrate having a transparent conductive oxide (TCO) film formed on a surface thereof, a dielectric mask having openings formed on a surface of the TCO film, a seed layer formed in the openings of the dielectric mask, and a copper plating later formed on the seed layer. In a method of forming a solar cell, a TCO film is applied to a surface of a silicon substrate, a dielectric mask is formed on a surface of the TCO film, a metal seed layer is applied to openings in the dielectric mask by in-situ hydrogen plasma treatment, and copper metal is plated onto the metal seed layer via light induced plating or field induced plating to form a copper electrode. The solar cell may then be annealed to form an indium-copper alloy which improves adhesion of the copper electrode.

### CROSS REFERENCES TO RELATED APPLICATIONS

This application claims priority to and the benefit of U.S. Provisional Application No. 62/172,428, filed on Jun. 8, 2015.

### STATEMENT REGARDING FEDERALLY SPONSORED RESEARCH

Not Applicable.

### BACKGROUND OF INVENTION

Solar cells have been commercially used for over one hundred years, but the cost of production and solar cell efficiency have combined to prevent solar cells from more widespread use. Today, many solar cells are produced using an expensive screen printing process that prints silver paste onto a transparent conductive oxide layer (TCO). Because of the costly nature of silver paste, other metallization schemes have been sought out.

One contemplated alternative to silver paste is copper plating. Copper is a factor of one hundred times cheaper than silver, and provides a conductivity between five and ten times higher than that of a polymer silver paste.

Currently, two prominent methods to plate copper on a TCO are in use: (1) copper electroplating on a physical vapor deposition (PVD) seed layer, and (2) light-induced plating (LIP) or field-induced plating (FIP) of copper with or without seed layer formation. While the use of copper is attractive, both methods require the use of complex manufacturing processes and techniques that greatly increase the cost, such that the benefits over silver paste printing are minimized. To achieve high efficiency, solar cells need copper lines with less than thirty microns width, and both discussed methods require expensive photolithography processes to achieve this resolution.

Therefore, a need in the art exists for a method of producing copper plated solar cells that can achieve the resolution of photolithography at a significantly lower cost.

### SUMMARY OF THE INVENTION

The present invention provides a novel metallization process that can overcome the disadvantages of existing copper plating techniques. The invention provides a high efficiency copper plated solar cell and a method of producing similar solar cells.

In one embodiment, a solar cell comprises a silicon substrate having transparent conductive oxide film on a surface, a dielectric mask deposited on a surface of the transparent conductive oxide film having openings therein, a metal seed layer formed in the openings of the dielectric mask, and a copper electrode formed on a surface of the metal seed layer.

In some embodiments, the transparent conductive oxide film comprises indium and oxygen, and may further comprise tin or zinc. The dielectric mask may be formed of silicon dioxide or silicon nitride. The metal seed layer may comprise indium. The solar cell may further comprise a tin or silver layer formed on the copper electrode, and may be a silicon heterojunction (SHJ) cell. The copper electrode can have a finger width between 1 and 50 microns.

A method of producing a copper plated solar cell is also provided. The method comprises (a) applying a transparent conductive oxide film to a surface of a silicon substrate, (b) forming a dielectric mask having openings on a surface of the transparent conductive oxide film, (c) applying a metal seed layer to the openings of the dielectric mask by in-situ hydrogen plasma treatment, and (d) light-induced plating or field-induced plating copper metal onto a surface of the metal seed layer to form a copper electrode.

In some embodiments, the method further comprises curing the resist material after screen printing or ink jet printing the resist material on the transparent conductive oxide film. In other embodiments, the method further comprises plating a layer of tin or silver on a surface of the copper electrode. In still other embodiments, the method further comprises annealing the solar cell for a period of time.

The dielectric mask thickness may be about 50-200 nanometers. In some embodiments, forming the dielectric mask comprises screen printing or ink jet printing a resist material on a surface of the transparent conductive oxide film, applying a dielectric film to the silicon substrate and the printed resist material, and removing the printed resist material so as to form the openings in the dielectric mask. Removing the printed resist material may be performed using low concentration caustic solutions or solvents. In alternative embodiments, the dielectric film is coated onto the silicon substrate via plasma-enhanced chemical vapor deposition or physical vapor deposition methods at temperatures at or below 100° C.

Applying a metal seed layer by in-situ hydrogen plasma treatment may be performed by in-situ reduction of indium. The copper plating may be designated such that light induced plating of copper is performed on an n-type side of the substrate, and field induced plating is performed on a p-type side of the substrate. Finally, annealing may range between five and thirty minutes, and may be performed at temperatures between 150° C. and 250° C.

The foregoing and other advantages of the invention will appear from the following detailed description. In the description, reference is made to the accompanying drawings which illustrate an embodiment of the invention.

### BRIEF DESCRIPTION OF THE DRAWINGS

The present disclosure is illustrated and described herein with references to various figures, in which:

FIG. 1A is a diagram of a solar cell with a transparent conductive oxide layer in accordance with the present disclosure.

FIG. 1B is a diagram of a solar cell in which a resist is applied to the transparent conductive oxide layer.

FIG. 1C is a diagram of a solar cell in which a dielectric coating is applied over the transparent conductive oxide layer and resist.

FIG. 1D is a diagram of a solar cell in which the resist and dielectric coating covering the resist have been removed.

FIG. 1E is a diagram of a solar cell in which a layer of seed metal is present on the surface of the transparent conductive oxide layer where the resist was removed.

FIG. 1F is a diagram of a solar cell in which copper is plated on the seed metal.

FIG. 1G is a diagram of a solar cell in which a layer of alloying is present between the copper and the seed metal.

FIG. 2 is a diagram of copper plated solar cell production known in the art.

FIG. 3 is a diagram of a copper plating method in accordance with the present disclosure.

FIG. 4 is a series of photos that shows the actual production of solar cells depicted in FIGS. 1B-1D.

### DETAILED DESCRIPTION OF THE INVENTION

Before the present materials and methods are described, it is to be understood that the terminology used herein is for the purpose of describing particular embodiments only, and is not intended to limit the scope of the present invention.

It must be noted that as used herein and in the appended claims, the singular forms “a”, “an”, and “the” include plural references unless the context clearly dictates otherwise. As well, the terms “a” (or “an”), “one or more” and “at least one” can be used interchangeably herein. It is also to be noted that the terms “comprising”, “including”, and “having” can be used interchangeably.

Unless defined otherwise, all technical and scientific terms used herein have the same meanings as commonly understood by one of ordinary skill in the art to which this invention belongs.

The present invention is directed to a method which can achieve the resolution of photolithography at a significantly lower cost and also avoid the disadvantages associated with electroplating and light-induced plating of copper on transparent conductive oxide (TCO) layers. At the same time, the method provides a cost effective solution to form a second antireflection coating in a solar cell and improves the conductivity and transparency of TCO layers using in-situ hydrogen doping. In various embodiments, the present disclosure provides a method of forming a metal grid on the surface of solar cells coated with TCO film and a high efficiency solar cell structure using this method. It is important to note that this method can be applied to both positive and negative terminals of the cell.

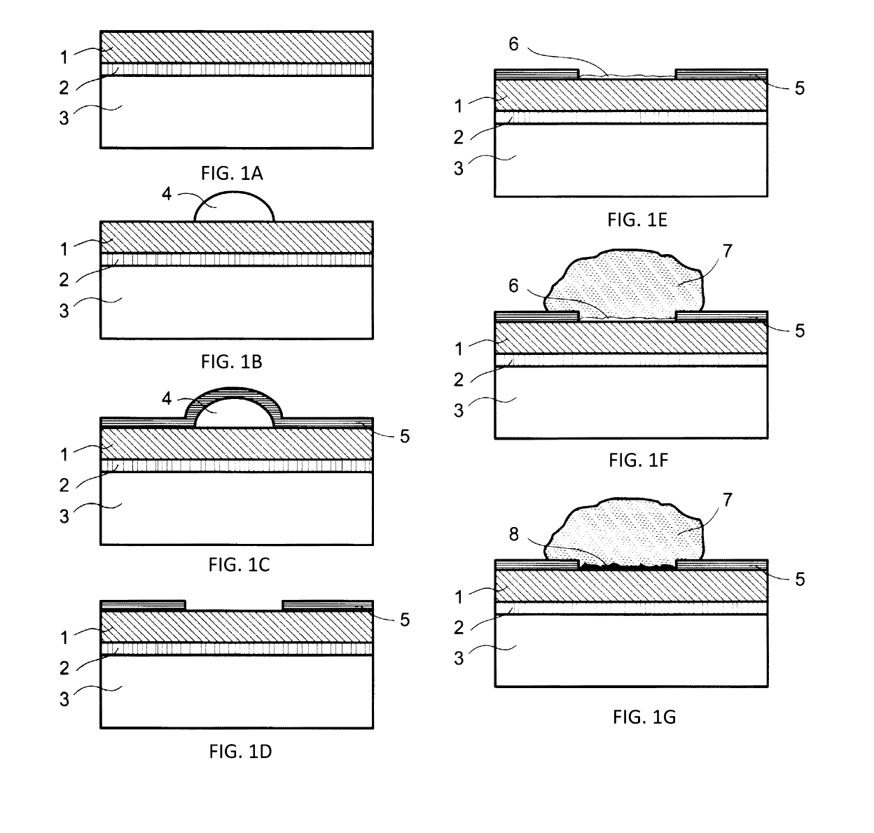

A starting substrate in this method is a solar cell with a TCO layer 1, as seen in FIG. 1A. The solar cell in FIG. 1A is a silicon heterojunction (SHJ) cell, which comprises a layer of amorphous silicon 2 and crystalline silicon wafer 3. In forming this solar cell, TCO 1 is deposited on top of doped amorphous silicon layers 2 to provide lateral conductivity, electrical contact formation, and light trapping. The TCO film comprises indium and oxygen, and in some cases comprises an indium-tin-oxide (ITO). In alternate embodiments, the TCO film comprises zinc, forming an indium-zinc-oxide (IZO). IZO layers are designed for use on the p-side of cells, due to its higher work function. Other TCO's with higher free carrier mobility may be used as well.

In FIG. 1B, a resist 4 is then printed and cured on top of TCO 1 to form a grid pattern, in the shape of either fingers or busbars. The resist is a low cost material capable of both withstanding at least 100° C. temperature and being further delaminated, etched, or removed in an alkaline solution, such as a sodium hydroxide solution, a potassium hydroxide solution, or ammonium hydroxide. The resist must also be capable of being deposited with high resolution on a textured surface. Because resolution is so important, the viscosity of the resist can be adjusted to accommodate the method of resist deposit. Higher viscosity resists allow higher resolution screen printing of resist. Lower viscosity resists can be sprayed on the surface of a solar cell through a shadow mask, or stencil. The resist sprayed on the mask can then be recollected to reduce per cell material consumption as well. Lower viscosity resists can also be used in an ink-jetting process. For example, a standard plating resist from Technic Inc., TechniSol UV-PR, may be used for screen printing. Other standard low cost screen-printable organic resists can be used as well.

The resolution of the copper plated fingers, which affects the efficiency of cells produced using this method, is influenced by the resolution of the resist lines. For this reason, resist lines of less than thirty microns width should be printed. For example, twenty micron wide lines can be screen printed with a stencil using high viscosity resist. One advantage of this method is that thick layers of resist are not required, which relaxes the requirements on the resist material formulation. Additionally, the resist does not serve as the plating mask, which further relaxes material requirements. This also enables using a jet printing method to deposit resist, which works well when thin layers of materials have to be deposited.

In FIG. 1C, a dielectric film 5 is deposited on top of the printed resist 4. For example, SiO₂ or SiNₓ films with fifty to two-hundred nanometer thickness can be used. If dielectric films with high hydrogen content are used, the conductivity and transparency of the underlying TCO layers can be further improved. The films are preferably deposited at low temperature in order to avoid damaging the resist 4. For example, plasma-enhanced chemical vapor deposition (PECVD) or physical vapor deposition (PVD) films deposited at a temperature below 100° C. can be used.

The refractive index and thickness of the films should be adjusted to work best with the underlying TCO layer 1 as a second antireflection coating. The deposited films should also withstand a subsequent copper plating, which is usually done in acidic solutions.

To avoid ghost plating, graded dielectric films can be used. In graded dielectric films, the top film is designed to have less hydrogen, such that the film is denser. Pinholes in thin dielectric films can be avoided by changing the orientation of the wafer during the deposition. Finally, subsequent hydrogen plasma treatment can cure the dangling bonds in the dielectric film. This reduces the number of nucleation sites on the surface of the film and thus reduces ghost plating.

In FIG. 1D, the resist 4 is lifted off, forming openings in the dielectric film layer 5. As stated previously, patterning the cells for subsequent plating can be a major cost component in the overall plating process. While the lift off process will depend on the particular resist formulation used, in some embodiments, lift off can be performed by exposing the cell to a solution that releases the resist. In one embodiment, flow patterning is done by lifting the deposited resist grid in a weak alkaline solution after a thin dielectric deposition. An alkaline solution having a mass percentage of 5% or less is an example weak alkaline solution. In some embodiments, low concentration caustic solutions or solvents can also be used for the lift off. A caustic solution having a mass percentage (m/m=m %=mass solute/mass total solution after mixing) of 5% or less is an example low concentration caustic solution. Non-limiting example low concentration caustic solutions are 2 m % sodium hydroxide, 2 m % potassium hydroxide, and 2 m % ammonium hydroxide. Care is needed because certain metals and substrates may not be that stable to alkaline solutions and so the mass percentage of the solution must be chosen based on the properties of the resist and the other materials in the presence of that solution, so that resist is removed at a much higher rate than the other materials.

Alternatively, the silicon-based dielectric films can be deposited on ITO using a shadow mask comprised of 20-micron-wide stainless steel wires. The mask can be magnetically coupled to the wafer and direction deposition of the silicon. For example, evaporation in a hydrogen atmosphere can provide a perfect resolution.

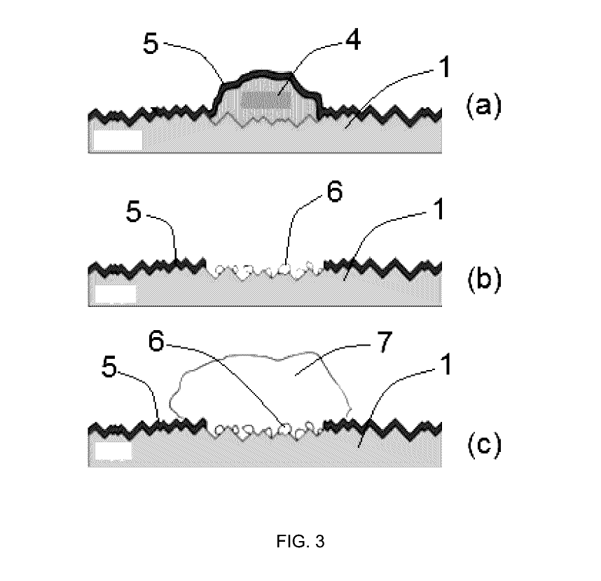

Within the openings in the dielectric layer 5, a seed or adhesion layer 6 is formed on the TCO by in-situ reduction of indium from the TCO using hydrogen plasma treatment, as shown in FIG. 1E. Indium droplets having ten to one hundred nanometer diameters are formed on the surface of the TCO 1 when it is exposed to hydrogen plasma at a temperature exceeding the melting point of indium, shown more clearly in FIG. 3. Alternatively, a uniform indium layer 6 without the formation of droplets can be reduced on the surface of the TCO at lower temperature, as seen in FIG. 1E. Thus, the relative concentration of indium can be increased from 5-10% in as-deposited films to 50-70% in hydrogen plasma treated film.

In FIG. 1F, copper 7 is plated on indium seeds or the indium layer 6 using light induced plating (LIP) on an n-type side of the cell or field induced plating (FIP) on a p-type side of the cell. The grid can optionally be finished by plating a thin layer of tin or silver on top of the copper 7 for soldering and moisture protection.

In FIG. 1G, the solar cell goes through an annealing cycle. For example, an annealing cycle lasting between five and thirty minutes at 200° C. in air can be used. Annealing accelerates interdiffusion of indium and copper and causes a thin indium-copper alloy 8 to form on the surface of the TCO. This alloyed region serves as an adhesion layer. Additionally, annealing may cause hydrogen from the dielectric films to diffuse into the TCO layer 1 where it can serve as a dopant, increasing both conductivity and transparency of the TCO 1.

Using the aforementioned technique, photovoltaic (PV) modules with 23% efficiency and lower cost as compared to conventional silicon PV modules can be created. The copper-SHJ cells may allow up to 20% levelized cost of energy (LCOE) reduction compared to aluminum back surface field (Al-BSF) modules when (1) the manufacturing cost of copper-SHJ cells is reduced and (2) the efficiency of PV modules in mass production reaches 23%, as it has here. The novel low cost patterning method displayed in FIGS. 1A-1G allows the formation of 30 micron-wide copper-plated fingers, which overcomes the need for expensive photolithographic processes required by existing copper plating techniques. With the increased conductivity of copper relative to silver, as well as the decrease in material cost, solar cells produced by the disclosed method will achieve 1-2% higher efficiency at a much lower cost.

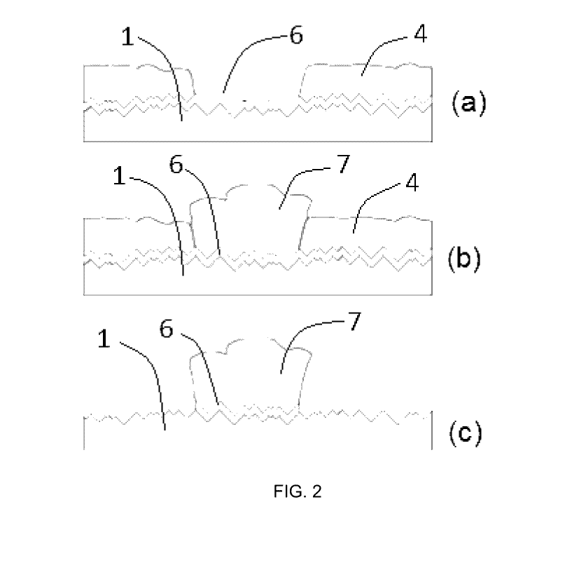

FIG. 2 shows the process steps followed by conventional electroplating processes that have proven to be too costly to replace silver paste printing. This is one of the main existing methods to plate copper on a TCO, copper electroplating on a PVD layer.

In the copper electroplating method, copper 7 is plated on a thin, ten to one hundred nanometer seed layer 6 formed on a TCO 1 by a PVD. In step (a), a seed layer 6 is patterned by laminating the entire wafer with a resist mask 4, the pattern created using photolithography or other alternative methods such as jetting the resist etchants or laser ablating the resist. Similarly, the resist mask can be formed by printing a resist pattern on the substrate through the screen or using various jet printing techniques. Once the resist mask 4 is formed, the seed layer 6 is contacted by metal electrodes and submerged into a plating solution. Copper electroplating shown in step (b) is initiated by passing the current through the metal seed layer 6. Usually five to twenty microns of copper 7 is plated. The metal grid is completed by capping the bulk copper with a thin tin or silver layer for moisture protection and soldering. Finally, a resist mask 4 is stripped and a thin PVD seed layer 6 is selectively etched, as can be seen in (c).

To achieve high efficiency, solar cells need copper lines with less than thirty micron width. In traditional electroplating methods such as that depicted in FIG. 2, this resolution is achieved using photolithography. Because materials and methods used in photolithography involve expensive photoresist, high resolution UV exposure, and resist stripping, the increased manufacturing cost reduces the attractiveness of copper plating. Cost is further increased due to the use of complicated contacting schemes, where probes with a buildup of copper have to be periodically replaced.

FIG. 3 provides a diagram of an alternative embodiment of the method shown in FIG. 1E. In (a), resist 4 has been patterned on to the TCO 1, and then subsequently coated in dielectric 5. In (b), the resist has been lifted off, exposing some of the TCO film 1. Direct plating of copper on the TCO leads to poor adhesion, so to overcome this shortfall, an additional adhesion layer comprised of tin, indium, or palladium may be used. Alternatively, by exposing this film surface to hydrogen plasma at around 150° C.-200° C. in melting point temperatures, metallic indium 6 can be reduced from the TCO surface to promote copper adhesion to the TCO. Finally, in (c), the copper is plated onto the TCO using either LIP or FIP, depending on which side of the cell is being plated. Once again, LIP will be used on an n-type side of the substrate, while FIP will be used on a p-type side of the substrate. The final resolution of plated copper fingers in the method is primarily determined by the resolution of the resist lines, which can be printed below thirty micron resolution and cleanly lifted off. As such, a high efficiency solar cell can be created.

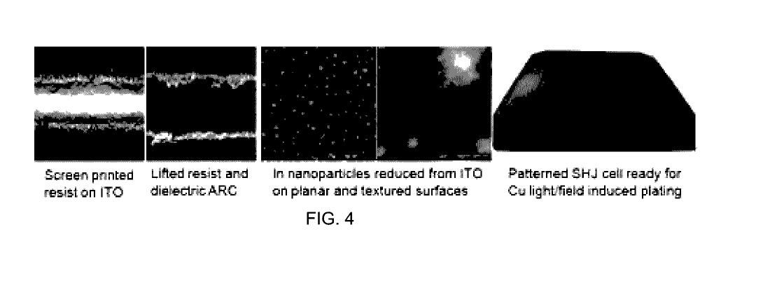

FIG. 4 shows microscopic views of the solar cell method disclosed. In the first picture, screen printed resist on an ITO is shown. In the next picture, dielectric has been deposited over the resist, and the resist has been lifted off. The third and fourth pictures show indium nanoparticles reduced from ITO on planar and textured surfaces. Finally, the last picture represents a patterned SHJ cell created according to the disclosed method, which is ready for copper LIP or FIP.

The presently disclosed solar cell and method of manufacturing provides a number of advantages over known copper electroplating techniques and FIP and LIP copper procedures. The disclosed method reduces the usage of resist per cell, as only 5% of the wafer area is laminated compared to 95% when a resist mask is used. The dielectric layer provides multiple new functions, serving as a resist mask, a second antireflection coating to allow 41 mA/cm² J_{SC} (short-circuit current density) in mass produced cells with having greater than 41 mA/cm² J_{gen} (current density), and as an ITO curing layer allowing 70 Ω/sq. sheet resistance while maintaining high transparency. The method allows the possibility of adjusting the thickness and refractive index of the dielectric antireflection coating (ARC) on the front and rear sides to optimize optical properties of encapsulated cells. The method also allows for contactless or soft contact plating compatible with less than one hundred micron thick wafer processing.

Optimization of the front layer of the front ITO layer is a standard problem in existing SHJ cell design, as the ITO is required to perform two functions with opposite material requirements. The ITO must (1) provide a lateral conductivity layer while (2) providing an antireflection coating with high transparency over the entire solar spectrum capable of absorption in silicon, which generally ranges from 300-1200 nm. The present invention overcomes these issues by providing the second dielectric antireflection coating. This allows thinner, more transparent ITO layers to be used in the formation of SHJ cells without sacrificing the ITO's antireflection properties. Acceptable conductivity of the thinner ITO layers is maintained due to the effect of the sheet resistance reduction of ITO capped with a hydrogenated SiO₂ layer.

Benefits of this approach have already been confirmed, as Regher Solar, an Arizona company, has achieved around 41 mA/cm² generation current density on 120 μm thick cells incorporating this method, while maintaining 60-70 Ω/sq. effective sheet resistance on the side exposed to the sun. To further increase generation current, even thinner ITO layers can be used, such as 50 nm thick or less.

Thinning ITO layer by H₂ plasma treatment may cause reliability concerns. To prevent or minimize copper diffusion through ITO, a thicker and more transparent IO layer can be used. In literature IO layers doped with hydrogen (IO:H) have been applied to SHJ solar cells to achieve a lower parasitic absorption compared to ITO. A drawback of using IO:H was a high contact resistance formed with screen printed silver, which required an additional thin ITO layer to be sputtered on top of IO:H. Although not yet tested, it is possible that reduction of In on the surface of IO:H can solve the issue with contact resistance. Arizona State University Solar Power Labs already has an RF sputter tool with IO target installed.

In another approach, TCOs based on Zn with higher work function can be attempted for Ni/copper plating on a p-side of the cell. IZO layers for contacting p-side emitters in SHJ cells have been developed as set forth herein. The higher work function of IZO (>5 eV) can favor the formation of ohmic contact with plated Ni, which can be a problem when plating on ITO.

### Adhesion Testing

To achieve stable adhesion of copper contacts plated on ITO with a plasma induced In adhesion layer, a number of tasks and tests have been planned. Through testing, a repeatable plasma treatment will be developed and the influence of the reduced In nanoparticles on adhesion will be further investigated. Alternative adhesion layer formation methods will also be developed, should plasma reduction have fundamental problems.

To perform these tests, SHJ cells with a dielectric mask on ITO will be prepared. The mask will be formed by lifting the resist coated with dielectric film. The resist will be deposited either by screen printing or by spinning and photolithographic patterning. The cells will use ITO film with the thickness and material composition previously optimized to produce 41 mA/cm² generation current and 70 Ω/sq. sheet resistance. H₂ plasma treatment conditions will then be ranged (hydrogen gas flow, plasma power, temperature, time) and the formation of In nanoparticles on the surface of the ITO will be observed using a scanning electron microscope (SEM). The creation of cells without nanoparticle formation will also be attempted in case oxygen depleted regions could help the adhesion. The cells will then be transferred to LIP bath to be plated with 10 microns of copper. After plating, the cells will be tested by a “tape test.” In case of good adhesion the solar cells will be transferred to the Arizona State University Photovoltaic Reliability Lab for peel force testing. This task will also test ITO/IO stacks, where IO is deposited on top of ITO and serves a sacrificial layer for In reduction. The cells with a dielectric mask will be sent to Technic Inc. to test their alternative approaches to the adhesion layer formation. If successful, Technic will transfer their process to the Arizona State University Solar Power Lab to be tested on a pilot line scale. Technic is developing a method where the cells are treated by a wet chemical solution with the formation of a thin Sn layer on the surface of ITO, and a similar process at the Arizona State University Solar Power Lab will be performed using a bath of proprietary solution produced by Technic.

### Plated Copper Electrode Reliability

A comprehensive reliability study looking at copper diffusion through an ITO barrier layer into silicon wafer will be performed. Literature suggests ITO to be a perfect barrier to copper diffusion at temperatures up to 700° C. However, the roughness of the textured silicon surface and subsequent plasma treatment may worsen the properties of ITO as a barrier. A series of experiments will be conducted which accelerate copper diffusion and monitor electrical performance of the copper plated cells. Thicker, more transparent IO layers and Sn barrier layers will also be tested in case extensive copper diffusion through the baseline ITO film occurs.

In this set of testing, the plated cells will be annealed for 500 hours at 200° C. in air, while fill factor (pFF), open circuit voltage (V_{OC}), and shunt resistance (R_{SH}) will be monitored. If diffusion occurs through ITO, copper can either become a recombination center in silicon to reduce V_{OC} and pFF, or form a shunt, which can be traced by the reduction of R_{SH}. Simultaneously 4-cell sub-modules will be prepared for reliability testing at the Arizona State University Photovoltaic Reliability Lab. UV stability testing at 10 kWhr/m² and 365 nm UV will occur for 100 hours. Thermal stability testing will occur for 100 cycles at −40/+85° C. Finally, moisture resistance testing, in particular a damp heat test set at 85% humidity at 80° C. for 100 hours will occur. If acceptable degradation rates are observed, a 4-cell submodule will be delivered to TUV Rheinland for certified testing. If issues with reliability arise, a thicker and more transparent IO layer will be used, which are already available at the Arizona State University Solar Power Lab. If the IO layer is not doped with Sn, conductivity of the IO layer may not be sufficient for use as a lateral conductor in SHJ cells. The IO layer is therefore doped with hydrogen. The source of hydrogen during sputtering can be, for example, water vapor. Doping the IO layer will be attempted from hydrogenated SiO₂, which is used as a dielectric mask and a second ARC. If a sufficient conductivity can be achieved, higher transparency of IO can allow depositing thicker layers making a better barrier to copper diffusion. Finally, the reliability approach will be tested with the deposition of a Sn layer and plating copper on top. The primary role of Sn is to serve as the adhesion layer in this example. However, if made relatively thick, for example, greater than ten nanometers, it can also provide shielding from copper diffusion.

### Depositing Resist Lines with 30-Micron Resolution

Two approaches will be attempted to develop a method of reducing the width of printed resist lines down to 30 microns. In one approach, a more viscous resist will be used in conjunction with a conventional screen printing method. In another approach, a less viscous resist will be sprayed through a stencil. In addition, ink-jetting of the resist and a wire shadow mask will be attempted with the less viscous resist.

With the capability to form 30-micron-wide copper plated fingers, it is expected that the technology will achieve 22% solar cell efficiency. The height of the finger will be greater than five microns, and more preferably greater than ten microns. If such aspect ratio cannot be achieved, wider fingers can still be used to deliver 22% efficiency with two busbars. A resist with higher viscosity than that used to produce the baseline cell will be produced, as well as a resist with lower viscosity than that used to produce the baseline cell. Higher viscosity resist will be deposited on the solar cells using a screen printer, for example, a Baccini screen printer. Appropriate screens and stencils will be designed and purchased. To quickly test spraying of the resist through the stencil, a spray coating photoresist will be used. After appropriate curing, either under UV light or on a hot plate, the resist lines will be inspected under the microscope. In an alternative approach, dielectric can be deposited using an in-situ shadow mask made of thin stainless steel wires. For example, 30-micron-wide flat stainless wires can be used. A good contact between the wires and solar cell will be ensured by magnetic coupling. The mask will be tested in thermal evaporation, sputtering, and PECVD tools. Finally, thin resist will be sprayed through a stencil. Additionally, gravure offset printing of the resist will be attempted.

While there has been shown and described what are at present considered certain embodiments of the invention, it will be obvious to those skilled in the art that various changes and modifications can be made therein without departing from the scope of the invention defined by the appended claims.

What is claimed is:

1. A solar cell comprising:
a silicon substrate having a transparent conductive oxide film on a surface thereof;
a dielectric mask deposited on a surface of the transparent conductive oxide film having openings therein;
a metal seed layer formed in the openings of the dielectric mask; and
a copper electrode formed on a surface of the metal seed layer.

2. The solar cell of claim 1, wherein the transparent conductive oxide film comprises indium and oxygen.

3. The solar cell of claim 2, wherein the transparent conductive oxide film further comprises tin.

4. The solar cell of claim 2, wherein the transparent conductive oxide film further comprises zinc.

5. The solar cell of claim 1, wherein the dielectric mask is formed of silicon dioxide or silicon nitride.

6. The solar cell of claim 1, wherein the metal seed layer comprises indium.

7. The solar cell of claim 1, further comprising a tin or silver layer formed on the copper electrode.

8. The solar cell of claim 1, wherein the solar cell is a silicon heterojunction cell.

9. The solar cell of claim 1, wherein the copper electrode has a finger width between 1 and 50 microns.

10. A method of forming a solar cell comprising:
(a) applying a transparent conductive oxide film to a surface of a silicon substrate;
(b) forming a dielectric mask having openings on a surface of the transparent conductive oxide film;
(c) applying a metal seed layer to the openings of the dielectric mask by in-situ hydrogen plasma treatment; and
(d) light-induced plating or field induced plating copper metal onto a surface of the metal seed layer to form a copper electrode.

11. The method of claim 10, wherein step (b) comprises:
screen printing or ink jet printing a resist material on a surface of the transparent conductive oxide film;
applying a dielectric film to the silicon substrate and the printed resist material; and
removing the printed resist material so as to form the openings in the dielectric mask.

12. The method of claim 10, further comprising:
(e) curing the resist material after screen printing or ink jet printing the resist material on the transparent conductive oxide film.

13. The method of claim 10, wherein the dielectric film is coated onto the silicon substrate via plasma-enhanced chemical vapor deposition or physical vapor deposition methods at temperatures at or below 100° C.

14. The method of claim 11, wherein the step of removing the printed resist material is performed using a caustic solution having a mass percentage of 5% or less.

15. The method of claim 10, wherein the dielectric mask has a thickness of about 50-200 nanometers.

16. The method of claim 10, wherein the step of applying a metal seed layer by in-situ hydrogen plasma treatment is performed by in-situ reduction of indium.

17. The method of claim 10, wherein light induced plating of copper is performed on an n-type side of the substrate, and field induced plating of copper is performed on a p-type side of the substrate.

18. The method of claim 10, further comprising:
(e) plating a layer of tin or silver on a surface of the copper electrode.

19. The method of claim 10, further comprising:
(e) annealing the solar cell for 5-30 minutes.

20. The method of claim 19, wherein the annealing process is performed between 150° C. and 250° C.
